(19) United States
(12) Patent Application Publication
(10) Pub. No.: US 2004/0126490 A1
(43) Pub. Date: Jul. 1, 2004

(54) Dry-paint film for application to a component

(75) Inventors: Walter Aichholzer, Hemmingen (DE); Reinhold Berkau, Ulm (DE); Thomas Gruber, Neu-Ulm (DE); Holger Rothenburger, Ulm (DE)

Correspondence Address: DAVIDSON, DAVIDSON & KAPPEL, LLC, 485 SEVENTH AVENUE, 14TH FLOOR, NEW YORK, NY, 10018, US

(73) Assignee: DaimlerChrysler AG, Stuttgart (DE)

(21) Appl. No.: 10/685,678

(22) Filed: Oct. 15, 2003

(30) Foreign Application Priority Data
Oct. 16, 2002 (DE) DE102 48 270.5-43

(51) Int. Cl. C23C 16/00

(52) U.S. Cl. 427/248.1; 427/402; 427/428; 427/421

(57) ABSTRACT

A dry-paint film for application to a component includes a support material, at least one pigmented paint layer and, if optionally, a top layer, in particular a transparent top layer. The paint layer includes two layers. The first layer, facing the support material, is applied to the support material by knife coating, rolling, pouring or printing, while the second layer is coated onto the first layer by atomization of the coating material.

Priority is claimed to German Patent Application No. DE 102 48 270.5-43, filed on Oct. 16, 2003, the entire disclosure of which is incorporated by reference herein.

### BACKGROUND

The present invention relates to a dry-paint film for application to a component and a process for producing a dry-paint film.

Generic dry-paint films are known for example from German Patent Documents DE 195 17 067 A1 and DE 195 17 068 A1, both of which are incorporated by reference herein. Both of these documents describe a film coated with two or more coats, and its use on a metallic support component, for automotive construction for example. Both inventions concern themselves with a polymer film to whose surface, if desired, a surfacer composition has been applied. At least one pigmented paint layer is coated onto the surface of the polymer film or onto the surfacer layer, and this paint layer is, according to the first cited document, sealed with a transparent polymer film or, according to the other document, overcoated with a transparent varnish.

Dry-paint films of this kind are increasingly being used as a substitute for conventional coating systems. The dry-paint films are produced independently of the later component and can for example be transported, stored and processed on rolls or the like. After the actual dry-paint film has been produced it is applied to the component it is intended to coat, which may be, for example, a bodywork component or any other component. It may be conceived for use both on metal components and on polymer components.

Known additionally from the prior art is a process for coating three-dimensionally curved surfaces of dimensionally stable substrates with a dry-paint film and also a process for producing such a dry-paint film. This process, which is described n European Patent Document EP 0 819 520 A2, gives a detailed description of the construction of a dry-paint film having a radiation-curable paint layer, and also further, general ideas relating to such dry-paint films.

The films, which are described by the prior art cited above make possible such a use. As compared with a conventional coating system, however, they have the decisive disadvantage that the colour brilliance and colour sensation differ very greatly with the direction from which the film, or the film-coated component, is viewed. In terms of appearance, the optical effects and paint qualities achievable by customary bodywork coating systems cannot be realized by way of dry-paint films of this kind.

### SUMMARY OF THE INVENTION

It is an object of the present invention to specify a dry-paint film, which allows precise reproduction of the optical effect of an automotive coating system and also its brilliance.

The present invention provides a process for producing a pigmented paint layer of a dry-paint film for application to a component comprising a support material and at least one pigmented paint layer. In order to produce the paint layer on a support material (3) comprising a sheet having a thickness of from 100 to 1200 μm: to start with, a first layer (7) having a dry layer thickness of between 10 and 50 μm is applied by knife coating, rolling, pouring or printing, after which a second layer (9) is applied to this first layer (7) by atomization, the dry layer thickness of the first layer (7) being greater by a factor of from 3 to 5 than the dry layer thickness of the second layer (9).

The pigmented paint layer forms the part, which is critical to the optical appearance of the dry-paint films. In accordance with the present invention this pigmented paint layer is constructed from at least two layers, the first of which, facing the support material, being comparatively thick and having been applied in particular by knife coating or rolling. In parallel to the two stated methods it is also possible to conceive of other methods, which permit similar layer thicknesses, e.g. pouring or screen printing. Atop this layer, applied for example by knife coating, a second layer is then applied by atomization. This atomization comprises the method, known from the application of coating systems, in which the second layer is coated on by means of electrostatic atomization or compressed-air atomization.

A dry-paint film constructed in this way has the advantage that application to a web of the support material can be made very simply and effectively as part of a continuous coating process. The use of the paint layer constructed in two stages means that, with minimum effort and essentially without flash-off times prior to coating, a very thin coated-on layer can be used to achieve an optical effect comparable with that of the automotive finishes that are presently the norm. This is possible especially when realizing effect finishes such as metallic finishes or the like, since in this case the flops in brightness and the brilliance can be reproduced identically to the optical effect of painted motor-vehicle outer-skin components.

The present invention also provides a dry-paint film for application to a component which is used as a bodywork component on a motor vehicle. The features describe a process for producing this same pigmented paint layer, where to start with a first paint layer is applied to the support material by knife coating, rolling or the like, after which a second, thinner paint layer is coated onto the first layer by atomization.

One particularly advantageous development of this process provides for the second layer to be coated onto the first layer in a wet-on-wet operation. This process, alongside the coating of the second layer onto a through-dried first layer, which is also possible in principle, has the decisive advantage that further optical effects can be achieved by the coating system. Moreover, in view of the fact that the first layer is not yet completely through-dried or is not yet completely dry at its surface, it is still receptive to parts of the solvent and/or binder of the second layer. The bond between the individual layers is thereby improved, so that the two layers adhere ideally to one another.

A particularly advantageous use for the above-described dry-paint film and, respectively, of the dry-paint film obtainable by the process of the invention, lies, as already mentioned at the outset, in the use thereof for application to a bodywork component of a vehicle.

### BRIEF DESCRIPTION OF THE DRAWINGS

Further advantageous embodiments of the invention will emerge from the claims and from the exemplary embodiment which is depicted below with reference to the drawings, in which:

FIG. 1 shows a depiction in principle of a construction for implementing the process of the invention; and

FIG. 2 shows a dry-paint film in accordance with the invention, in principle, and not to scale, in a cross-section.

### DETAILED DESCRIPTION

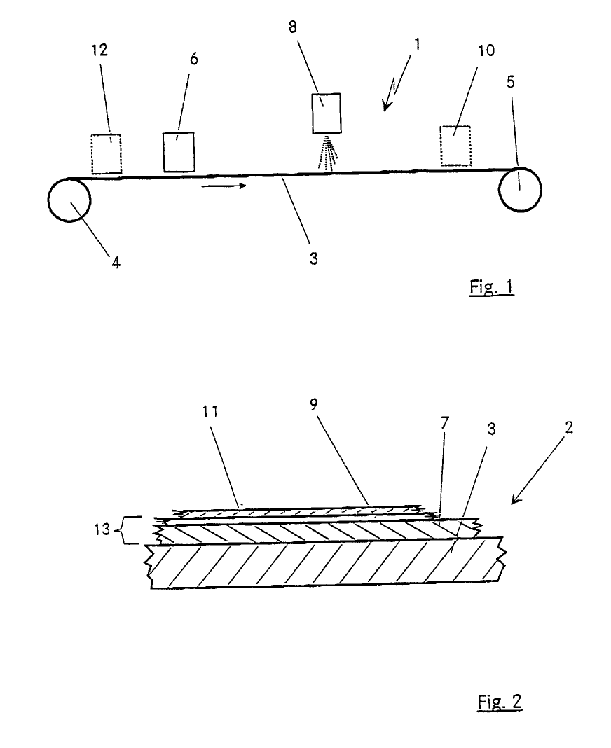

Evident from FIG. 1 is a construction in principle of an apparatus 1 for producing a dry-paint film 2, which is depicted in more detail in FIG. 2.

In the exemplary embodiment depicted here a support sheet 3 is moved from a stock roll 4 through the actual apparatus 1 and upon completion is rolled up again onto a further roll 5. In the course of this movement the support material 3 is coated, in a first station 6 of the apparatus 1, with a first layer composed of a pigmented paint 7, which is evident from FIG. 2. This coating of the first paint layer 7 in workstation 6 is accomplished by means of knife coating. In parallel with this, other coating techniques such as rolling, pouring or screen printing, for example, would also be conceivable. Following the application of the first paint layer 7 in the workstation 6 by knife coating, a second workstation, an atomizer 8, applies a further paint layer 9 by atomization. This atomization in the atomizer 8 is a pneumatic atomization or an electrostatic atomization. Both are known in principle from coating technology and require no further elucidation.

There are then two possibilities for the operating regime in the apparatus 1. A first option is to allow the first paint layer 7 to dry after workstation 6 before the second paint layer 9 is applied by means of the atomizer 8. In that case it would also be possible in principle to separate the apparatus 1 into two apparatuses and to perform the operations in succession. However, with a view to rationalising the production of such dry-paint films 2, it is sensible to conduct the coating operations in a continuous process, so that in the apparatus 1, immediately after the first paint layer 7 has been applied in the workstation 6 by knife coating, the second paint layer 9 is applied by atomization by means of the atomizer 8. For that purpose it is possible, for example, to use a wet-on-wet coating technique in which the second paint layer 9 is coated into the first paint layer 7 before the latter has dried completely.

As well as the optical effects which can be achieved in this way, which are an ideal recreation of a conventionally produced automotive finish, it is also possible to achieve improved adhesion of the second paint layer 9 to the first paint layer 7, since this layer still has free radicals and the like which have not yet dried off and which improve the adhesion of the second paint layer 9 to the surface of the first paint layer 7.

Depicted additionally in the apparatus 1 of the FIG. 1 exemplary embodiment, indicated in principle, is an optional workstation 10, which—if desired or required—applies a transparent top layer 11, which is evident from FIG. 2. This transparent top layer 11 may be composed of a transparent varnish layer, a laminated-on polymer layer, a laminated-on polymer film or, in particular, a UV-curing varnish layer.

In the here-depicted exemplary embodiment of the apparatus 1 in FIG. 1, the dry-paint film 2 is then rolled up as a semi-finished product onto the roll 5 and can be applied immediately to the corresponding components, bodywork components for example.

In addition to the workstations 6, 8 and 10 depicted here it is also possible in principle for one (or more) further workstation(s) 12 to be provided, which is likewise indicated in principle in FIG. 1. In this workstation 12, which in the processing direction of the film is located upstream of the application of the first paint layer 7 in the workstation 6, it is possible, for example, to apply an adhesion-promoting coating, a surfacer or the like to the support material 3, so that the strength and the adhesion properties of the individual paint layers on the support material 3 are improved overall.

Despite the atomizer 8, the production of the dry-paint film in the apparatus 1 allows very good paint utilization with very little overspray to burden the surrounding area, since, with a planar film and with continuous manufacture, a process of this kind is easier to manage than when coating curved surfaces, for example directly on the workpiece.

Depicted again in FIG. 2, then, in detail, is the construction of the dry-paint film 2, in a section, which is not shown to scale. The core and the major part of such a dry-paint film 2 is without doubt the support material 3, normally a polymer sheet. Depending on the application and on the use of the dry-paint film 2 the thicknesses of this support material 3 may vary. In the case for example of dry-paint films 2 which are to be coated onto metals, support material 3 thicknesses of from about 50 to 300 μm have proven to be sensible. Where, conversely, the dry-paint film 2 is to be applied to polymeric components, e.g. polymeric components of vehicle bodies, the inventors have found that support material 3 layer thicknesses of more than 500 μm, in particular between 700 and 1200 μm, are ideally suited to this purpose.

In the case of the layer construction depicted here this support material 3 then has applied to it, directly, the first paint layer, which constitutes the actual colour effect of the dry-paint film 2 and is composed of pigmented paint or basecoat material. This first paint layer 7, which as already mentioned earlier can be applied by knife coating, rolling, pouring or printing, forms the major part of the actual paint layer 13, which is composed of the first paint layer 7 and the second paint layer 9. Customary thicknesses of the first paint layer 7 will be in an order of magnitude of approximately 10 to 40 μm, based in each case on the dry layer thickness. This relatively thick first paint layer 7, which forms a hiding colour layer, then has coated onto it the second paint layer 9, by way of the atomizer 8. The thickness of the second paint layer 9 is much lower than that of the first paint layer 7, which allows a very rapid and rational layer construction. Because of the hiding first paint layer 7 there is also no need in this case to ensure a hiding application of colour, since the second paint layer 9 is only intended to produce optical effects.

In order to be able to obtain the optical effects comparable with those of the conventional vehicle finishes by means of wet coating materials, thicknesses of up to 20 μm for the second paint layer 7, based on the dry layer thickness, have proven to be advantageous. Normally in this context the proportion of the first paint layer 7 to the second paint layer 9 should be such that the first paint layer 7 is approximately 3 to 5 times thicker than the second paint layer 9. Customary paint systems, for example, envisage a first paint layer 7 in a dry layer thickness of approximately 20 μm, whereas the second paint layer in a dry layer thickness of approximately 5 μm, which is applied by the atomization, is sufficient to obtain the optical properties referred to at the outset.

What is claimed is:

1. A process for producing a pigmented paint layer of a dry-paint film for application to a component, the dry-paint film including a support material and at least one pigmented paint layer, the process including:
applying a first layer to the support material having a first dry layer thickness of between 10 and 50 μm by at least one of knife coating, rolling, pouring or printing; and
applying a second layer having a second dry layer thickness to the first layer by atomization, wherein the first dry layer thickness is greater than the second dry layer thickness by a factor of from 3 to 5.

2. The process as recited in claim 1, further comprising applying a transparent top layer to the second layer.

3. The process as recited in claim 2, wherein the transparent top layer is formed by UV-curing varnish.

4. The process as recited in claim 1, wherein the applying of the second layer is performed in a wet-on-wet operation, before the first layer has dried.

5. The process as recited in claim 1, wherein the applying of the second layer is performed after the first layer has dried.

6. The process as recited in claim 1, wherein the component is a bodywork component of a motor vehicle.

7. The process as recited in claim 1, wherein the support material has a thickness of from 100 to 1200 μm and

8. The process as recited in claim 1, wherein the component includes a polymer material and the support material has a thickness of from 700 to 1200 μm.

9. The process as recited in claim 1, wherein the component includes a metal and the support material has a thickness of from 50 to 300 μm.
